(19) United States
(12) Patent Application Publication
(10) Pub. No.: US 2026/0032864 A1
(43) Pub. Date: Jan. 29, 2026

(54) THERMAL MANAGEMENT ON GAMING SYSTEMS WITH MULTIPLE HEATPIPES THROUGH GRAPHITE BLOCK OTHOTROPY

(71) Applicant: DELL PRODUCTS L.P., Round Rock, TX (US)

(72) Inventors: TzuChau Chen, Wenshan District (TW); Travis North, Cedar Park, TX (US); Pomin Shih, Beitou District (TW)

(21) Appl. No.: 18/786,459

(22) Filed: Jul. 27, 2024

(51) Int. Cl. H05K 7/20

(52) U.S. Cl. CPC H05K 7/20336

(57) ABSTRACT

An information handling system includes a processor, a heat pipe, and a graphite plate The processor has a surface defining an x-y plane. The heat pipe has a major axis in an x-direction and is displaced from the processor in the z direction. The graphite plate is positioned between the processor and the heat pipe in the z-direction and in thermal contact with the processor and the heat pipe. The graphite plate is oriented to align a first high thermal conductivity direction in the z direction, to align a second high thermal conductivity direction in the y direction perpendicular to the major axis of the heat pipe, and to align a low thermal conductivity direction in the x direction parallel to major axis of the heat pipe.

### FIELD OF THE DISCLOSURE

The present disclosure generally relates to information handling systems, and more particularly relates to thermal management on a gaming system with multiple heatpipes through graphite block orthotropy.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a processor, a heat pipe, and a graphite plate. The processor includes a surface defining an x-y plane. The heat pipe has a major axis in an x-direction and is displaced from the processor in the z direction. The graphite plate is positioned between the processor and the heat pipe in the z-direction and in thermal contact with the processor and the heat pipe. The graphite plate is oriented to align a first high thermal conductivity direction in the z direction, to align a second high thermal conductivity direction in the y direction perpendicular to the major axis of the heat pipe, and to align a low thermal conductivity direction in the x direction parallel to major axis of the heat pipe.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIGS. 1A and 1B are block diagrams of a portion of a system illustrating thermal management of a processor according to at least one embodiment of the present disclosure;

FIG. 2 is a diagram illustrating a thermal management assembly according to at least one embodiment of the present disclosure; and

FIG. 3 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

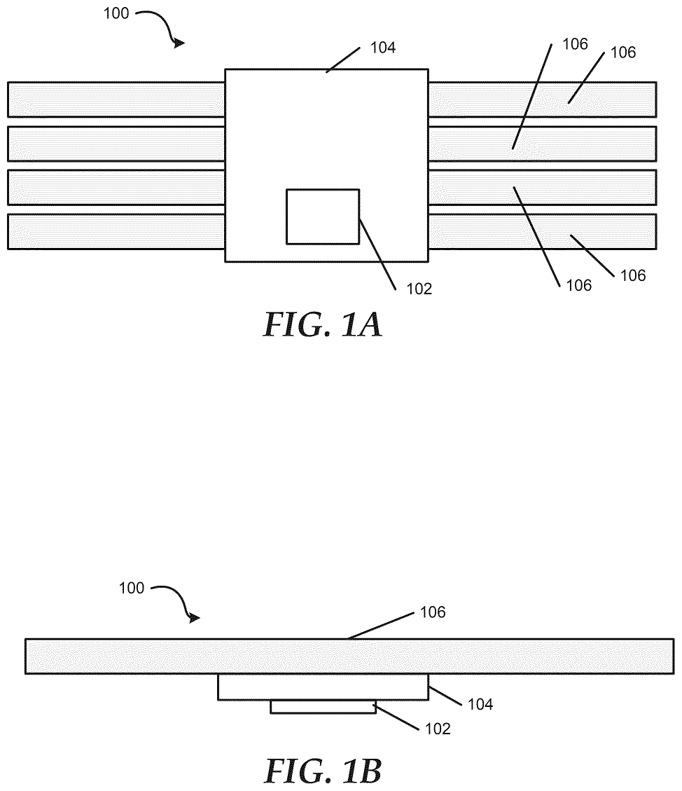

FIG. 1A illustrates a top view and FIG. 1B illustrates a side view of a thermal management assembly 100 of an information handling system, according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Thermal management assembly 100 includes chipset 102, graphite plate 104, and heat pipes 106. Chipset 102 can be a processor such as a central processing unit (CPU), a graphics processing unit (GPU), other heat generating chipset, or any combination thereof. Chipset 102 may be utilized in a gaming system, such that chipset may generate a large amount of heat that needs to be dissipated. Graphite plate 104 can be positioned on top of chipset 102, such that a surface of the chipset is in thermal contact with the graphite plate 104. In various embodiments, a thermal paste can be used between the chipset 102 and the graphite plate 104 to increase heat transfer. Heat pipes 106 can be positioned on top of graphite plate 104 and in thermal contact with the graphite plate 104.

In various embodiments, the graphite plate 104 includes a nickel plating and the heat pipes can be soldered to the nickel plating. In some embodiments, the graphite plate 104 can include a copper plating. Graphite plate 104 can be an orthotropic material, such that thermal conductivity of the graphite plate 104 is not the same in all directions. Specifically, the graphite plate 104 can have high thermal conductivity in a first direction and a second direction with low thermal conductivity in a third direction. The thermal conductivity in the first high thermal conductivity direction and the second high thermal conductivity direction can be at least about 1000 W/mk, such as at least about 1500 W/mk, but generally not greater than about 5000 W/mk. The thermal conductivity in the low thermal conductivity direction can be not greater than about 10 W/mk, such as not greater than about 5 W/mk, but generally not less than about 0.01 W/mk.

In various embodiments, the chipset 102, graphite plate 104, and heat pipes 106 can be stacked in a z-direction, with the heat pipes 106 aligned in a x-direction. The first high thermal conductivity direction can be aligned in the z-direction to move heat from the surface of the chipset 102 into the graphite plate 104 and up to the heat pipes 106. Additionally, the second high thermal conductivity direction can be aligned in a y-direction, perpendicular to the heat pipes 106 to rapidly transfer heat from the chipset 102 to all of the heat pipes 106. The low thermal conductivity direction can be aligned in the x-direction parallel to the heat pipes 106 as the heat pipes 106 can provide a high thermal conductivity path in the x-direction to take heat away from the chipset 102 and graphite plate 104 to one or more thermal dissipation devices. The thermal dissipation devices can include a heat sink with a high surface area to allow thermal exchange with the ambient environment. In some embodiments, the thermal dissipation device can be coupled with a fan to increase airflow across the thermal dissipation device to increase the transfer of heat from the thermal dissipation device to the air.

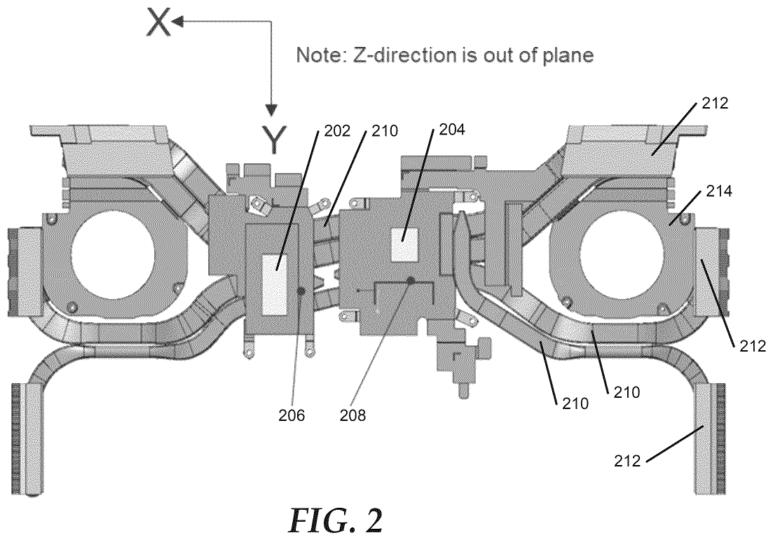

FIG. 2 is a thermal management assembly 200, according to at least one embodiment of the present disclosure. Thermal management assembly 200 is configured to remove heat from a chipset 202 and a chipset 204. Thermal management assembly 200 can include a graphite plate 206 and a graphite plate 208, heat pipes 210, and thermal dissipation devices 212. Graphite plate 206 can be thermally coupled to a surface of chipset 202 and graphite plate 208 can be thermally coupled to a surface of chipset 204. In various embodiments, thermal paste can be applied between chipset 202 and graphite plate 206 and between chipset 204 and graphite plate 208 to increase thermal transfer.

Heat pipes 210 can be thermally coupled to graphite plate 206 and graphite plate 208. In various embodiments, the graphite plates 206 and 208 can include a nickel plating and the heat pipe 210 can be soldered to the nickel plating. In some embodiments, the graphite plates 206 and 208 can include a copper plating and the heat pipe 210 can be soldered to the copper plating.

In various embodiments, graphite plates 206 and 208 can be orthotropic, such that thermal conductivity of the graphite plates 206 and 208 are not the same in all directions. Specifically, the graphite plates 206 and 208 can have high thermal conductivity in a first and a second direction with low thermal conductivity in a third direction. The thermal conductivity in the first high thermal conductivity direction and the second high thermal conductivity direction can be at least about 1000 W/mk, such as at least about 1500 W/mk, but generally not greater than about 5000 W/mk. The thermal conductivity in the low thermal conductivity direction can be not greater than about 10 W/mk, such as not greater than about 5 W/mk, but generally not less than about 0.01 W/mk.

In various embodiments, the first high thermal conductivity direction can be aligned with the direction of stack-up (z-direction) such that heat can be transferred through the stack from the chipset 202 or 204, through the graphite plate 206 or 208, and to the heat pipes 210. The second high thermal conductivity direction can be aligned perpendicular to the heat pipes 210 (y-direction). This can be useful in spreading the heat among multiple heat pipes. The low thermal conductivity direction can be aligned parallel to the heat pipes 210 (x-direction) as the heat pipes can transport the heat along the x-direction.

In various embodiments, the heat pipes 210 can conduct the heat to thermal dissipation devices 212. The thermal dissipation devices 212 can transfer the heat to the environment by thermal exchange with air. Fans 214 can be used to increase airflow across the thermal dissipation devices 212.

Thermal modeling of thermal management assembly 200 comparing a copper block with graphite blocks in various orientations is shown in Table 1. Using graphite in the Y-Z orientation resulted in 2 degree benefit.

TABLE 1
CPU/GPU temperature comparison

| | | Graphite X-Z | Graphite Y-Z | Graphite X-Y |
|---|---|---|---|---|
| | | Kx = Kz = 1500 | Ky = Kz = 1500 | Kx = Ky = 1500 |
| | Copper | W/mk | W/mk | W/mk |
| | K = 400 W/mk | Ky = 5 W/mk | Kx = 5 W/mk | Kz = 5 W/mk |
| GPU Tj | 85.95 C. | 86.84 C. | 83.32 C. | 143.55 C. |
| (130 W) | | | | |
| CPU Tj | 78.27 C. | 78.45 C. | 76.55 C. | 109.21 C. |
| (45 W) | | | | |

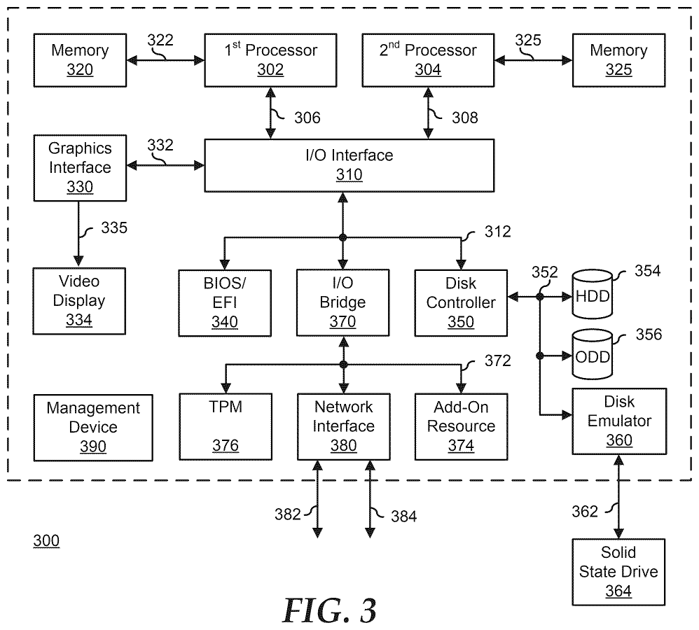

FIG. 3 shows a generalized embodiment of an information handling system 300 according to an embodiment of the present disclosure. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described below and operates to perform one or more of the methods described below. Information handling system 300 includes a processors 302 and 304, an input/output (I/O) interface 310, memories 320 and 325, a graphics interface 330, a basic input and output system/universal extensible firmware interface (BIOS/UEFI) module 340, a disk controller 350, a hard disk drive (HDD) 354, an optical disk drive (ODD) 356, a disk emulator 360 connected to an external solid state drive (SSD) 364, an I/O bridge 370, one or more add-on resources 374, a trusted platform module (TPM) 376, a network interface 380, a management device 390, and a power supply 395. Processors 302 and 304, I/O interface 310, memory 320, graphics interface 330, BIOS/UEFI module 340, disk controller 350, HDD 354, ODD 356, disk emulator 360, SSD 364, I/O bridge 370, add-on resources 374, TPM 376, and network interface 380 operate together to provide a host environment of information handling system 300 that operates to provide the data processing functionality of the information handling system. The host environment operates to execute machine-executable code, including platform BIOS/UEFI code, device firmware, operating system code, applications, programs, and the like, to perform the data processing tasks associated with information handling system 300.

In the host environment, processor 302 is connected to I/O interface 310 via processor interface 306, and processor 304 is connected to the I/O interface via processor interface 308. Memory 320 is connected to processor 302 via a memory interface 322. Memory 325 is connected to processor 304 via a memory interface 327. Graphics interface 330 is connected to I/O interface 310 via a graphics interface 332 and provides a video display output 336 to a video display 334. In a particular embodiment, information handling system 300 includes separate memories that are dedicated to each of processors 302 and 304 via separate memory interfaces. An example of memories 320 and 330 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 340, disk controller 350, and I/O bridge 370 are connected to I/O interface 310 via an I/O channel 312. An example of I/O channel 312 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 310 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 340 includes BIOS/UEFI code operable to detect resources within information handling system 300, to provide drivers for the resources, initialize the resources, and access the resources. BIOS/UEFI module 340 includes code that operates to detect resources within information handling system 300, to provide drivers for the resources, to initialize the resources, and to access the resources.

Disk controller 350 includes a disk interface 352 that connects the disk controller to HDD 354, to ODD 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits SSD 364 to be connected to information handling system 300 via an external interface 362. An example of external interface 362 includes a USB interface, an IEEE 3394 (Firewire) interface, a proprietary interface, or a combination thereof. Alternatively, solid-state drive 364 can be disposed within information handling system 300.

I/O bridge 370 includes a peripheral interface 372 that connects the I/O bridge to add-on resource 374, to TPM 376, and to network interface 380. Peripheral interface 372 can be the same type of interface as I/O channel 312 or can be a different type of interface. As such, I/O bridge 370 extends the capacity of I/O channel 312 when peripheral interface 372 and the I/O channel are of the same type, and the I/O bridge translates information from a format suitable to the I/O channel to a format suitable to the peripheral channel 372 when they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as I/O interface 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Management device 390 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 300. In particular, management device 390 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 300, such as system cooling fans and power supplies. Management device 390 can include a network connection to an external management system, and the management device can communicate with the management system to report status information for information handling system 300, to receive BIOS/UEFI or system firmware updates, or to perform other task for managing and controlling the operation of information handling system 300.

Management device 390 can operate off of a separate power plane from the components of the host environment so that the management device receives power to manage information handling system 300 when the information handling system is otherwise shut down. An example of management device 390 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 390 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An information handling system comprising:
a processor, the processor having a surface defining an x-y plane;
a heat pipe, the heat pipe having a major axis in an x-direction and displaced from the processor in the z direction; and
a graphite plate positioned between the processor and the heat pipe in the z-direction and in thermal contact with the processor and the heat pipe, the graphite plate oriented to align a first high thermal conductivity direction in the z direction, to align a second high thermal conductivity direction in the y direction perpendicular to the major axis of the heat pipe, and to align a low thermal conductivity direction in the x direction parallel to major axis of the heat pipe.

2. The information handling system of claim 1, wherein the graphite plate includes a nickel plating.

3. The information handling system of claim 2, wherein the heat pipe is soldered to the nickel plating.

4. The information handling system of claim 1, wherein the thermal conductivity in the first high thermal conductivity direction and the second high thermal conductivity direction is at least 1000 W/mk.

5. The information handling system of claim 4, wherein the thermal conductivity in the first high thermal conductivity direction and the second high thermal conductivity direction is at least 1500 W/mk.

6. The information handling system of claim 5, wherein the thermal conductivity in the first high thermal conductivity direction and the second high thermal conductivity direction is not greater than 5000 W/mk.

7. The information handling system of claim 1, wherein the thermal conductivity in the low thermal conductivity direction is not greater than 10 W/mk.

8. The information handling system of claim 7, wherein the thermal conductivity in the low thermal conductivity direction is not greater than 5 W/mk.

9. The information handling system of claim 8, wherein the thermal conductivity in the low thermal conductivity direction is at least 0.01 W/mk.

10. The information handling system of claim 1, wherein the processor is a central processing unit (CPU), a graphics processing unit (GPU), or any combination thereof.

11. A thermal management assembly for a processor comprising:
a graphite plate thermally coupled to a surface of the processor, wherein the surface of the processor defining an x-y plane;
one or more thermal pipes thermally coupled to the graphite plate, the thermal pipes oriented with a major axis in the x direction; and
one or more thermal dissipation devices coupled to the heat pipes;
wherein the graphite plate is oriented to align a first high thermal conductivity direction in the z direction, to align a second high thermal conductivity direction in the y direction perpendicular to the major axis of the heat pipe, and to align a low thermal conductivity direction in the x direction parallel to major axis of the heat pipe.

12. The thermal management assembly of claim 11, wherein the graphite plate includes a nickel plating.

13. The thermal management assembly of claim 12, wherein the heat pipe is soldered to the nickel plating.

14. The thermal management assembly of claim 11, wherein the thermal conductivity in the first high thermal conductivity direction and the second high thermal conductivity direction is at least 1000 W/mk.

15. The thermal management assembly of claim 14 wherein the thermal conductivity in the first high thermal conductivity direction and the second high thermal conductivity direction is at least 1500 W/mk.

16. The thermal management assembly of claim 15, wherein the thermal conductivity in the first high thermal conductivity direction and the second high thermal conductivity direction is not greater than 5000 W/mk.

17. The thermal management assembly of claim 11, wherein the thermal conductivity in the low thermal conductivity direction is not greater than 10 W/mk.

18. The thermal management assembly of claim 17, wherein the thermal conductivity in the low thermal conductivity direction is not greater than 5 W/mk.

19. The thermal management assembly of claim 11, wherein the processor is a central processing unit (CPU), a graphics processing unit (GPU), or any combination thereof.

20. An information handling system comprising:
a processor, the processor having a surface defining an x-y plane;
a heat pipe, the heat pipe having a major axis in an x-direction and displaced from the processor in the z direction;
a graphite plate positioned between the processor and the heat pipe in the z-direction and in thermal contact with the processor and the heat pipe, the graphite plate oriented to align a first high thermal conductivity direction in the z direction, to align a second high thermal conductivity direction in the y direction perpendicular to the major axis of the heat pipe, and to align a low thermal conductivity direction in the x direction parallel to major axis of the heat pipe;
one or more thermal dissipation devices coupled to the heat pipe; and
a thermal paste located in between the processor and the graphite plate.
